(19) United States
(12) Patent Application Publication
(10) Pub. No.: US 2004/0169176 A1
(43) Pub. Date: Sep. 2, 2004

(54) Methods of forming thin film transistors and related systems

(76) Inventors: Paul E. Peterson, Ft. Davis, TX (US); James Stasiak, Lebanon, OR (US)

Correspondence Address: HEWLETT-PACKARD DEVELOPMENT COMPANY, Intellectual Property Administration, P.O. Box 272400, Fort Collins, CO, 80527-2400, US

(21) Appl. No.: 10/376,431

(22) Filed: Feb. 28, 2003

(51) Int. Cl. H01L 29/04

(52) U.S. Cl. 257/59

(57) ABSTRACT

Methods of forming thin film transistors and related systems are described. In one embodiment, a method forms source/drain material over a substrate using a low temperature formation process. A channel layer is formed over the substrate using a low temperature formation process. A gate insulating layer is formed over the substrate using a low temperature formation process. A gate is formed over the substrate using a low temperature formation process. The low temperature formation processes that are utilized are conducted at temperatures that are no greater than about 200-degrees C.

### TECHNICAL FIELD

This invention relates to methods of forming thin film transistors and related methods.

### BACKGROUND

Thin film transistors (TFTs) are used in a variety of applications that utilize semiconductor devices such as, for example, various microelectronic circuits that are utilized in displays such as flat panel displays, other displays and the like. One of the things that continues to challenge those who design and fabricate thin film transistors is development of low-cost methods of manufacturing TFTs and resultant low-cost TFT structures.

There are a number of ways to reduce the cost of TFT development. For example, one can look at the manufacturing process itself and attempt to streamline or otherwise reduce the complexities associated with manufacturing TFTs. That is, there are methods of fabricating TFTs which, by virtue of the processing steps involved, are either or both of expensive to employ, and technically complex (which, incidentally, drives up the cost of fabrication). Additionally, one can look at the types of materials that are utilized to form the TFTs. For example, some substrates that support the TFT structures can typically be more cost effective than others. This is because certain types of substrates can be processed in a manner that is less expensive than other types of substrates. With these types of substrates, however, there are trade-offs that are made with respect to the materials and processing steps utilized during the TFT formation process.

Cost effective TFT manufacturing processes and resultant structures continue to be a challenge.

### SUMMARY

Methods of forming thin film transistors and related systems are described.

In one embodiment, a method forms source/drain material over a substrate using a low temperature formation process. A channel layer is formed over the source/drain material using a low temperature formation process. A gate insulating layer is formed over the channel layer using a low temperature formation process. A gate is formed over the gate insulating layer using a low temperature formation process. The low temperature formation processes that are utilized are conducted at temperatures that are no greater than about 200-degrees C.

In yet another embodiment, a method forms source/drain material over a substrate using at least one low temperature formation process to provide TFT sources and drains. A channel layer is formed over the substrate using a low temperature formation process. The channel layer comprises a different material than the source/drain material and comprises amorphous silicon. Portions of the channel layer that are to define channels for individual TFTs are exposed to laser conditions sufficient to recrystallize the portions. A gate insulating layer is formed over the substrate using a low temperature formation process. A gate is formed over the substrate using a low temperature formation process. The low temperature formation processes that are utilized are conducted at temperatures no greater than about 200-degrees C.

In yet another embodiment, a thin film transistor comprises a plastic substrate and a pair of low-temperature-formed, source/drain regions supported by the substrate. A blanket-deposited, low-temperature-formed channel layer is provided over the substrate and comprises different material than the source/drain material. The channel layer defines a channel region for the TFT. A blanket-deposited, low-temperature-formed gate insulating layer is provided over the channel layer, and a low-temperature-formed gate is disposed over the channel region.

### BRIEF DESCRIPTION OF THE DRAWINGS

FIG. 1 is a diagrammatic sectional view of a substrate, in process, in accordance with one embodiment.

FIG. 2 is a view of the FIG. 1 substrate at a processing step subsequent to that shown in FIG. 1 and in accordance with an embodiment of the present invention.

FIG. 3 is a view of the FIG. 1 substrate at a processing step subsequent to that shown in FIG. 2 and in accordance with an embodiment of the present invention.

FIG. 4 is a view of the FIG. 1 substrate at a processing step subsequent to that shown in FIG. 3 and in accordance with an embodiment of the present invention.

FIG. 5 is a view of the FIG. 1 substrate at a processing step subsequent to that shown in FIG. 4 and in accordance with an embodiment of the present invention.

FIG. 6 is a view of the FIG. 1 substrate at a processing step subsequent to that shown in FIG. 5 and in accordance with an embodiment of the present invention.

FIG. 7 is a view of the FIG. 1 substrate at a processing step subsequent to that shown in FIG. 6 and in accordance with an embodiment of the present invention.

FIG. 8 is a view of the FIG. 1 substrate at a processing step subsequent to that shown in FIG. 7 and in accordance with an embodiment of the present invention.

FIG. 9 is a diagrammatic sectional view of a substrate and associated TFT in accordance with another embodiment.

### DETAILED DESCRIPTION

Overview

Embodiments of the methods and resultant systems described below provide low-cost, highly manufacturable TFTs. The cost benefits that can be achieved with embodiments of the resultant TFT structures are provided, to some degree, by trading off on some of the performance characteristics of the TFT itself. This tradeoff, however, still provides TFTs with reasonable quality that can be utilized in various electronics.

Low temperature processing techniques are used in embodiments described herein. In one embodiment, “low temperature” is intended to include temperatures that are generally lower than, or at least no higher than the glass transition temperature of the substrate being employed. That is not to say that temperatures cannot venture above the glass transition temperature for a short period of time in some embodiments. Such temperature ventures should not, however, adversely affect or otherwise impact the substrate in these embodiments.

In certain embodiments, flexible and/or plastic substrates, such as flexible plastic substrates, are utilized to support the TFT structures. While glass transition temperatures vary among different plastic substrates, a reasonable bounding temperature for low-temperature processing for many suitable plastics is no greater than about 200-degrees C. It is to be appreciated, however, that higher bounding temperatures can result depending on the choice of substrate material.

Exemplary Process Flow

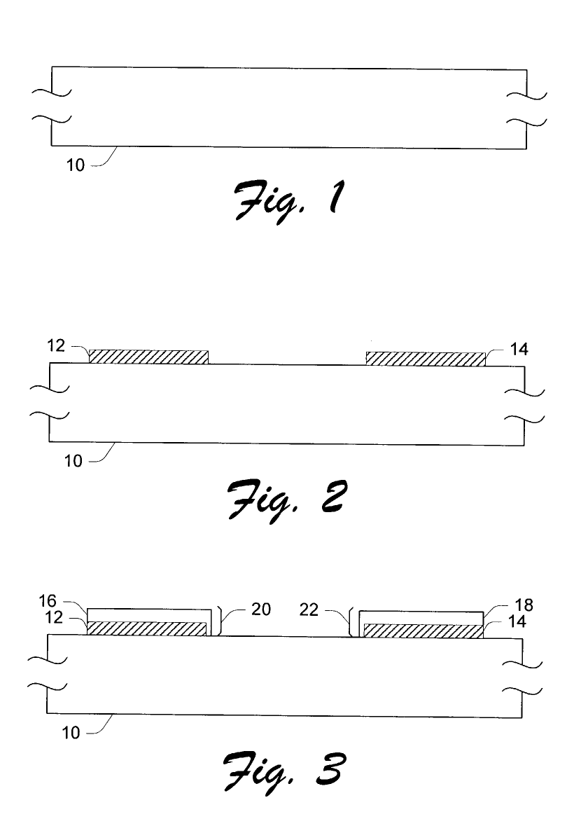

Referring to FIG. 1, a substrate in process is generally indicated at 10 and can comprise any suitable substrate on which TFT structures can be formed in accordance with the embodiments described herein. Suitable substrate materials include, without limitation, silicon, glass, polyimide, Kapton, Mylar, and various other polymeric or plastic materials. In some embodiments, the substrate material is selected such that it is flexible. Examples of flexible substrates include a variety of plastic substrate materials. In some embodiments, such flexible substrates are processed utilizing a roll-to-roll processing technique in which the substrate material is provided in a roll-form, and subsequently unrolled and processed in an assembly line-type of approach.

In some embodiments, selection of a suitable substrate material can be driven by one or more of the following: a desire to select a flexible material, a desire to select a material that can be processed in accordance with low-temperature processing techniques, and a desire to select a material that is transparent (e.g., to permit back side illumination).

Before forming the TFT structures, substrate 10 can be cleaned in a manner that is typical for the type of substrate material being employed.

Referring to FIG. 2, conductive material 12, 14 is formed over the substrate. In this embodiment, formation of the conductive material takes place using a low-temperature formation process. Any suitable process can be used and any suitable material, such as aluminum, or some other type of metal or metal alloy, can be used. Formation of material 12, 14 can be optional, with such material serving as contact pads for subsequently-formed source/drain regions. If conductive material 12, 14, is not formed, contact pads can be formed later in the process.

As examples of how conductive material 12, 14 can be formed, consider the following.

Prior to deposition of the conductive material, a masking layer can be formed over the substrate and patterned to open windows where the conductive material is to be deposited and the sources and drains for the TFTs are to be defined. The masking layer can comprise any suitable material such as a photomask that is subsequently patterned, for example using a laser, to open up the windows. The windows can also be mechanically opened using, for example, an embossing and lift off technique For example, vias can be patterned over the source and drain regions using an imprinting or stamping process. This process comprises applying a soft stencil material, such as PMMA, over the entire substrate and then, using a prefabricated mold, making impressions over the source/drain regions to effectively displace the PMMA and leave a void over the S/D regions. Typically, an oxygen reactive ion etch can then be used to clean the surface over which the source/drain regions are to be formed. After the embossing or stamping step, metal can be sputtered, evaporated, or otherwise formed over the entire substrate and into the void above the source/drain regions. Next, the stencil material (e.g. PMMA) can be lifted off to leave behind the S/D metal contacts. This process can be performed at low temperatures and without any photolithography steps and without any etching (dry or wet) to define the metal features.

As another example of how conductive material 12, 14 can be formed over the substrate, such material can be formed over the substrate using ink-jet microprinting techniques. There is considerable work underway within the industry that is exploring ink jet microprinting of conductive material. It has already been shown that conductive organic materials such as PEDOT can be precisely deposited using ink jet processing. Furthermore, work has been ongoing to develop ink jet deposition tools for organic LED manufacturing. Additionally, there is considerable work focused on the ink jet deposition of metallic and semiconducting nanoparticles suspended in a fluid. This work has shown that it is possible to ink jet deposit materials like CdSe and to provide for the precise placement of metallic and semiconducting features. For the particular application discussed in this document, one could pattern the source/drain regions with a suspension of metallic or semiconducting nanoparticles using an array of ink jet print heads in a fast, low cost roll-to-roll sequence.

In this process, the conductive material is effectively applied utilizing the combination of a firing chamber that receives the material that is to be deposited and one or more firing structures, such as a firing resistor, to nucleate the material so as to cause it to be ejected from the firing chamber. Very precise deposition can be achieved utilizing these techniques.

The conductive material can also be formed by sputtering or otherwise forming the material over the entire substrate (e.g. without a masking layer), and then laser ablating or otherwise removing the material to form the desired conductive material 12, 14 to define contact pads for the subsequently-formed sources and drains for the TFTs that are to be formed.

Referring to FIG. 3, source/drain material 16, 18 is formed over the substrate. In this example, source/drain material 16, 18 is formed over and in electrical communication with conductive material 12, 14, respectively. Any suitable techniques and material can be utilized to form the source/drain material 16, 18. Forming source/drain material 16, 18 as shown provides source/drain islands 20, 22, respectively, each of which comprises multiple layers of conductive material. Although only two individual layers are shown in the figure, it is to be appreciated that additional layers can be formed to provide the sources and drains for the TFTs that are formed.

For example, where a masking layer was previously utilized, the same masking layer can be used to allow the source/drain material 16, 18 to be formed over the substrate. Such can be accomplished using, for example, a low-temperature CVD process to deposit doped silicon or polysilicon over the substrate.

As another example, and one in which a masking layer was not previously utilized to selectively form the conductive material 12, 14, the source/drain material 16, 18 can be formed over the entire substrate and then patterned to provide the resultant structures shown in FIG. 3. Patterning can take place using any suitable techniques. For example, patterning can take place through the use of emboss and lift off techniques such as those described above. Alternately, patterning can take place by using laser ablation.

Optionally, an insulator layer can be formed over the substrate between source/drain islands 20, 22. Such layer can be formed using any suitable techniques. But one exemplary technique can comprise microprinting the layer over the substrate between the source/drain islands.

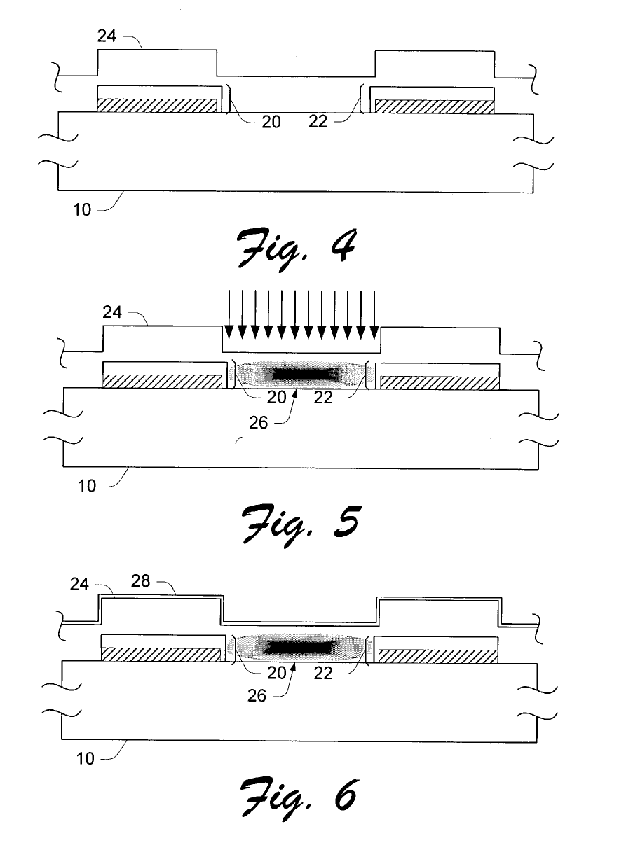

Referring to FIG. 4, a channel layer 24 is formed over the substrate and the source/drain islands 20, 22 respectively. In one embodiment, the channel layer is formed using low-temperature techniques that blanket deposit the layer over the entire substrate. For example, low-temperature CVD or sputtering techniques can be utilized to form the channel layer. In one embodiment, the channel layer is formed from amorphous silicon or a-Si. Using a low-temperature formation technique typically results in a lower quality channel layer. Recall, however, that one of the advantages of utilizing the formation techniques described herein is that the overall fabrication cost is kept desirably low.

As an alternative to the above-mentioned a-Si channel layer, in one embodiment the channel layer can be formed from an organic material, such as pentacene. Any suitable organic material can be utilized. In this example, formation of the pentacene channel layer takes place utilizing low temperature formation techniques among which include evaporation, spin coating, and dip coating. Additionally, when an organic material is utilized for the channel layer, such material can be formed over and cover the metal source/drain pads (i.e. conductive material 12, 14), without the presence of any doped regions (i.e. source/drain material 16, 18).

In the event that the channel layer is formed from a-Si, a region that is to underlie the gate can be selectively recrystallized using a laser recrystallization technique to provide polysilicon. Laser recrystallization of a-Si (also referred to as “Sequential Lateral Solidification” or “SLS”), essentially involves using the energy provided by a laser to radiate and locally melt a film or surface to enable it to solidify into a homogeneous structure.

Referring to FIG. 5, a region 26 is selectively recrystallized using SLS to provide polysilicon within the channel. Recrystallizing the a-Si desirably modifies the electrical properties of the material between the source and drain by increasing the channel mobility. For additional background on SLS, the reader is referred to the following references: U.S. Pat. Nos. 6,368,945, 6,322,625, and 6,346,462. Additional background material on SLS can be found in the following papers: R. Sposilli, J. Im, Applied Physics A 67, pp. 273-276 (1998); M. Crowder, P. Carey, et al., IEEE Electron Device Letters 19[8], (1998); and Sposilli et al., Mat. Res. Soc. Symp. Proc. Vol. 452, 956-957, 1997.

In the event that the channel layer is formed from an organic material, such as pentacene, then laser recrystallization is not utilized.

As an important aside, consider the following. Using a-Si followed by laser recrystallization forms TFTs that are n-channel devices—that is, the majority carriers are electrons. Using organic materials such as pentacene for the channel layers forms TFTs that are p-channel devices. Accordingly, incorporating both types of materials in the same process flow can provide complementary devices that are both n- and p-type.

Referring to FIG. 6, a gate insulating layer 28 is formed over the substrate. In the illustrated and described embodiment, the gate insulating layer 28 is blanket deposited over the entire substrate using a suitable low-temperature process. Examples of low temperature processes include plasma-enhanced CVD or PECVD, and sputtering. A suitable deposition process is described in Stasiak et al., “High Quality Deposited Gate Oxide MOSFETs and the Importance of Surface Preparation”, IEEE Electron Device Letters, Vol. 10, No. 6, 1989.

Any suitable materials can be used for the gate insulating layer, examples of which include various oxides (e.g. SiO₂), nitrides, oxynitrides and the like, although it is more desirable to use an oxide material. In embodiments that utilize an organic material for the channel layer, the gate insulating layer can be formed from materials such as insulating polymers like polyvinylphenol, polycarbonate, and the like.

Note that the gate insulating layer formation step is a blanket deposition and that, in this example, the gate insulating layer is not patterned. Accordingly, in some of the examples, there has been no patterning since the formation of the source/drain islands 20, 22. This is advantageous from the standpoint of keeping the cost of the manufacturing process desirably low. Additionally, formation of the described TFTs can effectively be performed using typically additive processes. This helps to keep manufacturing costs low, while at the same time reduces the chances of damaging underlying layers, such as might occur using a subtractive process. Additionally, in most if not all of the embodiments, wet chemistries can be avoided which helps to ensure the integrity of not only the underlying layers, but the substrate as well.

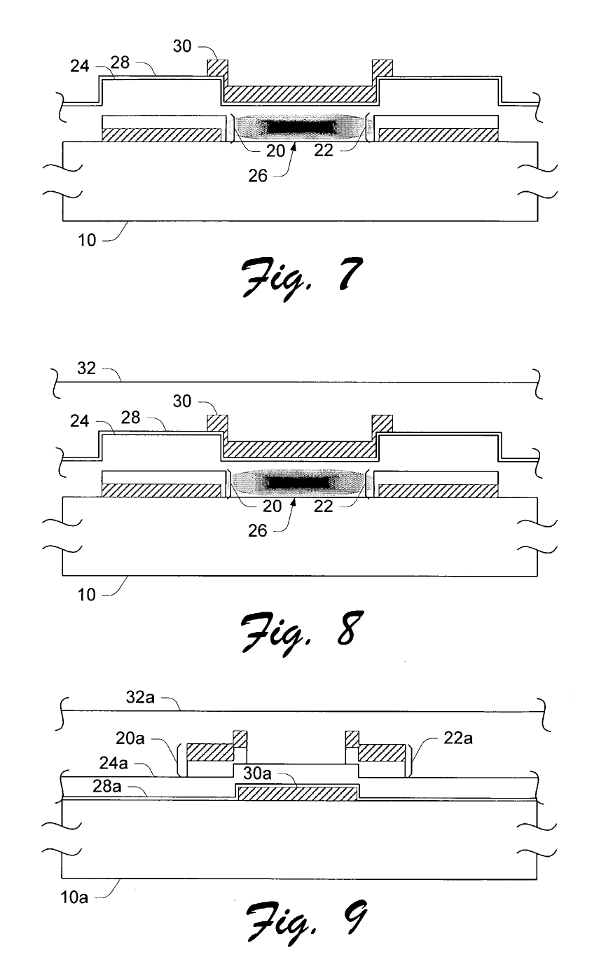

Referring to FIG. 7, a gate 30 is formed over the substrate and specifically, over the channel region and overlaps with portions of source/drain islands 20, 22 respectively. Gate 30 can be formed using any suitable techniques.

For examples of suitable techniques by which the gate can be formed, consider the following.

Prior to deposition of the gate material, a masking layer can be formed over the substrate and patterned to open a window where the gate material is to be deposited. The masking layer can comprise any suitable material such as a photomask that is subsequently patterned using, for example, a laser to open up the window. The window can also be mechanically opened using, for example, an embossing technique. After the window is opened up, the gate material can be deposited as through, for example, sputtering, evaporation, or any other suitable technique given the desire to maintain the processing at low temperatures. Once deposited, the masking layer and additional gate material that is not utilized to form the gate can be removed. Note that this is an additive process.

As another example of how the gate material can be formed over the substrate, such material can be formed over the substrate using ink-jet microprinting techniques. Here, the conductive material is effectively applied in a precise pattern using ink jet technology. Ink jet technology typically utilizes the combination of a firing chamber that receives the material that is to be deposited and one or more firing structures, such as a firing resistor, to nucleate the material so as to cause it to be ejected from the firing chamber. Very precise deposition can be achieved utilizing these techniques. Note that this is also an additive process.

The gate material can also be formed by sputtering or otherwise forming the material over the entire substrate (e.g. without a masking layer), and then laser ablating or otherwise removing the material to form the desired gate 30. Additionally, embossing and lift off techniques can be used to form the gate.

Any suitable material, such as aluminum, or some other type of metal or metal alloy, can be used for the gate. Other materials that are suitable for use as a gate include conducting polymers such as PEDOT (poly(3,4-ethylenedioxythiophene)) or polyaniline. These materials can work very nicely in an inkjet microprinting process.

Referring to FIG. 8, after formation of the gate, a passivating layer 32 can be formed over the substrate. Any suitable materials can be utilized for the passivating layer. For example, a low-temperature process can form a standard insulating layer over the substrate. Alternately, a plastic or polymeric laminate sheet can be applied over the substrate to passivate the substrate.

Following passivation, vias can be patterned over contact pads if needed. This can be done using, for example, laser ablation.

It is to be appreciated and understood that while the above-described process is directed to forming top-gated TFTs, similar techniques can be utilized to form bottom-gated TFTs.

Referring to FIG. 9, an exemplary bottom-gated TFT is shown. Like numerals from the above-described embodiments have been utilized, where appropriate, to depict like elements, with differences being indicated through the use of the suffix “a”.

In this example, a substrate 10a is provided and a gate 30a is formed thereover. The gate can be formed using any of the techniques described above, e.g. either the additive or subtractive techniques. A gate insulating layer 28a is formed over the substrate and is desirably blanket deposited over the entire substrate. A channel layer 24a is similarly formed or otherwise blanket deposited over the substrate. In the event that the channel layer is formed from a-Si, a laser recrystallization step can follow the channel layer formation. In the event that an organic material is utilized for the channel layer, then laser recrystallization is not utilized. Source/drain islands 20a, 22a, respectively are formed over the substrate. Any techniques mentioned above can be utilized to form the source/drain islands. Subsequently, a passivation layer 32a is formed over the substrate.

Conclusion

Various described embodiments can enable different types of substrate materials to be utilized in connection with a low-cost, low-temperature TFT formation process. Various described embodiments can effectively reduce the number of process steps by using predominately additive processes. This can enable TFTs to be placed directly on the products in connection with which they are used.

Although the disclosure has been described in language specific to structural features and/or methodological steps, it is to be understood that the appended claims are not limited to the specific features or steps described. Rather, the specific features and steps are exemplary forms of implementing this disclosure.

1. A thin film transistor (TFT) forming method comprising:
forming source/drain material over a substrate using a low temperature formation process;
forming a channel layer over the source/drain material using a low temperature formation process;
forming a gate insulating layer over the channel layer using a low temperature formation process; and
forming a gate over the gate insulating layer using a low temperature formation process;
the low temperature formation processes being conducted at temperatures that are no greater than about 200-degrees C.

2. The method of claim 1, wherein the acts of forming the source/drain material comprise forming a masking layer over the substrate and opening windows in the masking layer over the substrate where the source and drain are to be defined.

3. The method of claim 2, wherein the act of opening windows in the masking layer is performed using a laser.

4. The method of claim 2, wherein the act of opening windows is performed by mechanically opening windows.

5. The method of claim 4, wherein the act of mechanically opening windows comprises using an embossing technique.

6. The method of claim 2, wherein the acts of forming the source/drain material comprise performing one or more of sputtering, evaporating, and chemical vapor depositing the source/drain material.

7. The method of claim 1, wherein the acts of forming the source/drain material comprises performing one or more of sputtering and evaporating the source/drain material.

8. The method of claim 7 further comprising after performing said acts of forming the source/drain material, selectively removing source/drain material to define a source and drain for the TFT.

9. The method of claim 8, wherein the act of selectively removing source/drain material comprises using laser ablation to remove the material.

10. The method of claim 1, wherein at least one of the acts of forming the source/drain material comprises microprinting the source/drain material on the substrate.

11. The method of claim 1, wherein the acts of forming the source/drain material comprise using an embossing and lift off technique.

12. The method of claim 1, wherein the act of forming the source/drain material comprises forming a silicon-containing layer over the substrate.

13. The method of claim 12, wherein the silicon-containing layer comprises doped silicon.

14. The method of claim 12, wherein the silicon-containing layer comprises polysilicon.

15. The method of claim 1, wherein the act of forming the channel layer comprises chemical vapor depositing the channel layer.

16. The method of claim 1, wherein the act of forming the channel layer comprises sputtering the channel layer.

17. The method of claim 1, wherein the act of forming the channel layer comprises forming amorphous silicon over the source/drain material.

18. The method of claim 17 further comprising after forming the channel layer, exposing portions of the channel layer to laser conditions sufficient to recrystallize the portions.

19. The method of claim 18, wherein the act of exposing the portions of the channel layer to the laser conditions forms polysilicon.

20. The method of claim 1, wherein the act of forming the channel layer comprises forming an organic material over the source/drain material.

21. The method of claim 20, wherein the organic material comprises pentacene.

22. The method of claim 20, wherein the act of forming the organic material over the substrate comprises at least one of evaporating, spin coating, and dip coating the organic material over the substrate.

23. The method of claim 1, wherein the act of forming the channel layer comprises:
forming amorphous silicon over the source/drain material and subsequently exposing portions of the amorphous silicon to laser conditions sufficient to recrystallize the portions to provide n-type devices; and
forming an organic material over other portions of the source/drain material to provide p-type devices.

24. The method of claim 1, wherein the act of forming the gate insulating layer comprises blanket depositing the gate insulating layer over the channel layer and not subsequently patterning the gate insulating layer to form individual gates for the TFTs.

25. The method of claim 1, wherein the act of forming the gate comprises forming a masking layer over the substrate and opening a window in the masking layer over the substrate where the gate is to be defined, and subsequently forming gate material over the substrate.

26. The method of claim 1, wherein the act of forming the gate comprises microprinting the gate over the substrate.

27. The method of claim 1, wherein the act of forming the gate comprises forming gate material over the substrate and then removing some of the gate material to define the gate.

28. A thin film transistor (TFT) forming method comprising:
forming source/drain material over a substrate using at least one low temperature formation process to provide TFT sources and drains;
forming a channel layer over the substrate using a low temperature formation process, the channel layer comprising a different material than the source/drain material and comprising amorphous silicon;
exposing portions of the channel layer that are to define channels for individual TFTs to laser conditions sufficient to recrystallize the portions;
forming a gate insulating layer over the substrate using a low temperature formation process; and
forming a gate over the substrate using a low temperature formation process;
the low temperature formation processes being conducted at temperatures no greater than about 200-degrees C.

29. The method of claim 28, wherein the act of forming the source/drain material comprises forming a masking layer over the substrate and opening windows in the masking layer over the substrate where the sources and drains are to be defined.

30. The method of claim 29, wherein the act of opening windows in the masking layer is performed using a laser.

31. The method of claim 29, wherein the act of opening windows is performed by mechanically opening windows.

32. The method of claim 29, wherein the act of opening windows is performed by mechanically opening windows using an embossing technique.

33. The method of claim 29, wherein the act of forming the source/drain material comprises performing one or more of sputtering, evaporating, and chemical vapor depositing the source/drain material.

34. The method of claim 28, wherein the act of forming the source/drain material comprises performing one or more of sputtering and evaporating the source/drain material.

35. The method of claim 34 further comprising after performing said act of forming the source/drain material, selectively removing source/drain material to define sources and drains for the TFTs.

36. The method of claim 34 further comprising after performing said act of forming the source/drain material, selectively removing source/drain material to define sources and drains for the TFTs using laser ablation to remove the material.

37. The method of claim 28, wherein the act of forming the source/drain material comprises microprinting at least some source/drain material on the substrate.

38. The method of claim 28, wherein the act of forming the source/drain material comprises using an embossing and lift off technique to form at least some of the source/drain material.

39. The method of claim 28, wherein the act of forming the channel layer comprises chemical vapor depositing the channel layer over the substrate.

40. The method of claim 28, wherein the act of forming the channel layer comprises sputtering the channel layer over the substrate.

41. The method of claim 28, wherein the act of forming the gate insulating layer comprises blanket depositing the gate insulating layer over the substrate and not subsequently patterning the gate insulating layer to form individual gates for the TFTs.

42. The method of claim 28, wherein the act of forming the gate comprises forming a masking layer over the substrate and opening a window in the masking layer over the substrate where the gate is to be defined, and subsequently forming gate material over the substrate.

43. The method of claim 28, wherein the act of forming the gate comprises microprinting the gate over the substrate.

44. The method of claim 28, wherein the act of forming the gate comprises forming gate material over the substrate and then removing some of the gate material to define the gate.

45. The method of claim 28 furthering comprising performing the recited acts in the order in which they are recited.

46. The method of claim 28 further comprising performing the recited acts to form bottom-gated TFTs.

47. A thin film transistor (TFT) comprising:
a plastic substrate;
a pair of low-temperature-formed, source/drain regions supported by the substrate;
a low-temperature-formed channel layer blanket deposited over the substrate and comprising different material than the source/drain material, the channel layer defining a channel region for the TFT;
a low-temperature-formed gate insulating layer blanket deposited over the channel layer; and
a low-temperature-formed gate disposed over the channel region.

48. The TFT of claim 47, wherein the substrate comprises a flexible substrate.

49. The TFT of claim 47, wherein the substrate comprises a transparent substrate.

50. The TFT of claim 47, wherein the substrate comprises a flexible, transparent substrate.

51. An electronic embodying the TFT of claim 47.
